(19) United States
(12) Patent Application Publication
(10) Pub. No.: US 2024/0107888 A1
(43) Pub. Date: Mar. 28, 2024

(54) PIEZOELECTRIC COMPOSITE MATERIAL, ACTUATOR, AND PREPARATION METHOD OF ACTUATOR

(71) Applicant: NANJING UNIVERSITY OF AERONAUTICS AND ASTRONAUTICS, Nanjing (CN)

(72) Inventors: Hongli JI, Nanjing (CN); Jinhao QIU, Nanjing (CN); Chao ZHANG, Nanjing (CN); Congchong TAO, Nanjing (CN); Yuemin DU, Nanjing (CN); Jiao QU, Nanjing (CN)

(73) Assignee: NANJING UNIVERSITY OF AERONAUTICS AND ASTRONAUTICS, Nanjing (CN)

(21) Appl. No.: 18/140,251

(22) Filed: Apr. 27, 2023

(30) Foreign Application Priority Data
Sep. 28, 2022 (CN) 2022111892168

(51) Int. Cl. H10N 30/00; H10N 30/06; H10N 30/092; H10N 30/20; H10N 30/853; H10N 30/87

(52) U.S. Cl. CPC H10N 30/1061; H10N 30/06; H10N 30/092; H10N 30/20; H10N 30/853; H10N 30/875

(57) ABSTRACT

Provided are a piezoelectric composite material, an actuator, and a preparation method of the actuator, relating to the technical field of piezoelectric composite material actuators. The piezoelectric composite material includes an upper interdigital electrode layer, a piezoelectric fiber composite layer and a lower interdigital electrode layer which are arranged in sequence from top to bottom. The upper interdigital electrode layer, the piezoelectric fiber composite layer and the lower interdigital electrode layer each are of a parallelogram structure. A piezoelectric ceramic fiber array is embedded on the piezoelectric fiber composite layer; and the piezoelectric ceramic fiber array is of a parallelogram structure. By arranging the piezoelectric ceramic fiber array of the parallelogram structure, the effective area of an actuator can be increased, and then the actuation performance of the actuator can be improved.

### CROSS-REFERENCE TO RELATED APPLICATION

This patent application claims the benefit and priority of Chinese Patent Application No. 2022111892168, filed with the China National Intellectual Property Administration on Sep. 28, 2022, the disclosure of which is incorporated by reference herein in its entirety as part of the present application.

### TECHNICAL FIELD

The present disclosure relates to the technical field of piezoelectric composite material actuators, in particular to a piezoelectric composite material, an actuator and a preparation method of the actuator.

### BACKGROUND

Piezoelectric composite material is a composite material with piezoelectric effect, which is obtained by combining a piezoelectric ceramic phase material with a polymer phase material in a certain communicating way. In addition to retaining the advantages of large actuation deformation, fast response, wide frequency response range and good stability of the traditional piezoelectric ceramics, it also overcomes the disadvantages of large brittleness of ceramics and difficulty in integrating with curved structures. The characteristics of the piezoelectric composite material are mainly determined by the communication mode of the phases. At present, the piezoelectric composite layer in the commonly used piezoelectric fiber composite material actuator is formed by compounding the rectangular-section piezoelectric ceramic fibers with the polymer matrix in a 1-3 or 2-2 communication mode, and the piezoelectric composite layer is encapsulated by the upper and lower interdigital electrode layers (Note: the first number in the communication mode indicates a self-communication mode of the piezoelectric phase, and the second number indicates a self-communication mode of the polymer phase: 2-2 indicates that the piezoelectric ceramic phase and the polymer phase are self-connected in a two-dimensional plane and respectively extend in their respective planes; and 1-3 indicates that the piezoelectric ceramic phase is self-connected in a one-dimensional plane, while the polymer phase is self-connected in a three-dimensional space). The use of fibrous ceramic phase increases the compatibility of composite materials, so that the composite materials can be used in large planar or non-planar cases. Meanwhile, the polarization direction and electric field direction parallel to the fiber are introduced through the use of interdigital electrode introduces, which makes full use of the advantage of high longitudinal piezoelectric constant d33 of piezoelectric ceramics, improves the output deformation ability of the actuator, and further strengthens the anisotropy characteristics of the actuator device. Therefore, the piezoelectric fiber composite materials have been widely used in the fields of actuation deformation control, vibration and noise reduction, structural health monitoring and energy collection.

At present, the commonly used piezoelectric fiber composite materials and actuators are of a rectangular configuration. During the processing of piezoelectric ceramic fibers, the mechanical cutting direction is parallel to the long edge of the appearance of the final formed actuator, thus obtaining the piezoelectric ceramic fiber array of the rectangular configuration. Positive and negative electrode buses of upper-surface and lower-surface interdigital electrode layers of the actuator are arranged on both sides of the piezoelectric fiber array, and positive and negative electrode branches extended from the buses are perpendicular to the piezoelectric fiber and alternately arranged at equal intervals along the fiber length direction. When an external excitation voltage is applied, the actuator will output deformation in its long edge direction (in a d₃₃ mode) and width direction (in a d₃₁ mode). The actuator is adhered to the surface of engineering structure to actuate the telescopic deformation or bending deformation of the structure, and the purpose of active control of the engineering structure is achieved by applying an excitation voltage signal to the actuator. However, in practical application, the implementation of the device actuation is greatly limited by the appearance configuration of the traditional rectangular piezoelectric fiber composite material actuator. Taking the common torsion demand for actuating cantilever beam type structures as an example: when the rectangular piezoelectric fiber composite material actuator is used to implement structural deformation actuation, if an attachment direction of the actuator (i.e., a piezoelectric fiber direction) is parallel or perpendicular to the beam axis, the cantilever beam may undergo pure bending deformation; and if an attachment direction of the actuator forms an angle of ±45° with the beam axis, the cantilever beam may generated effective torsional deformation. However, in practical application, as the dimension of the engineering structure is fixed, and when the rectangular actuator is integrated with the structure, the effective area of the actuator is limited and incapable of completely covering the structure, the utilization rate of the surface space of the cantilever beam structure is low, which greatly weakens the great reduction of the final torsional actuation performance of the device.

### SUMMARY

An objective of the present disclosure is to provide a piezoelectric composite material, an actuator, and a preparation method of the actuator. The piezoelectric composite material is applied to the actuator. By arranging the piezoelectric ceramic fiber array of a parallelogram structure, the effective area of the actuator can be increased, and then the actuation performance of the actuator can be improved.

In order to achieve the above object, the present disclosure provides the following solution:

A piezoelectric composite material includes an upper interdigital electrode layer, a piezoelectric fiber composite layer and a lower interdigital electrode layer which are arranged in sequence from top to bottom.

The upper interdigital electrode layer, the piezoelectric fiber composite layer and the lower interdigital electrode layer each are of a parallelogram structure.

A piezoelectric ceramic fiber array is embedded on the piezoelectric fiber composite layer; and the piezoelectric ceramic fiber array is of a parallelogram structure.

Alternatively, a first polymer colloidal layer is provided between the upper interdigital electrode layer and the piezoelectric fiber composite layer.

A second polymer colloid layer is provided between the piezoelectric fiber composite layer and the lower interdigital electrode layer.

Alternatively, the piezoelectric ceramic fiber array includes multiple piezoelectric ceramic blocks.

The multiple piezoelectric blocks have the same shape and size, and the multiple piezoelectric ceramic blocks each are of a parallelogram structure.

The bottom edges of the multiple piezoelectric ceramic blocks are in the same direction; and the spacing distance between any two adjacent piezoelectric ceramic blocks is equal.

Alternatively, the upper interdigital electrode layer includes a substrate, a positive electrode, and a negative electrode.

The positive electrode and the negative electrode are arranged on the same side surface of the substrate in an interdigital manner.

The substrate is of a parallelogram structure.

Alternatively, the positive electrode includes a first main electrode wire, a second main electrode wire, and multiple first branch electrode wires.

The first main electrode wire is arranged along the bottom edge of the substrate.

The second main electrode wire is arranged along a first adjacent edge of the bottom edge of the substrate; and the first adjacent edge is an adjacent edge with an obtuse angle with the bottom edge of the substrate.

One end of the first main electrode wire intersects with one end of the second main electrode wire at an obtuse angle vertex on the bottom edge of the substrate.

The length of the first main electrode wire is smaller than that of the bottom edge of the substrate.

The length of the second main electrode wire is smaller than that of the first adjacent edge.

The multiple first branch electrode wires are arranged on the substrate in parallel.

One end of each of the first branch electrode wires is connected to the first main electrode wire or the second main electrode wire; and the multiple first branch electrode wires are arranged perpendicular to the first adjacent edge.

The spacing distance between any two adjacent first branch electrode wires is equal.

Alternatively, the negative electrode includes a third main electrode wire, a fourth main electrode wire, and multiple second branch electrode wires.

The third main electrode wire is arranged along an opposite edge of the bottom edge of the substrate.

The fourth main electrode wire is arranged along a second adjacent edge of the bottom edge of the substrate; and the second adjacent edge is an adjacent edge with an acute angle with the bottom edge of the substrate.

One end of the third main electrode wire intersects with one end of the fourth main electrode wire at an obtuse angle vertex on the bottom edge of the substrate.

The length of the third main electrode wire is equal to that of the first main electrode wire.

The length of the fourth main electrode wire is equal to that of the second main electrode wire.

The multiple second branch electrode wires are arranged on the substrate in parallel.

One end of each of the second branch electrode wires is connected to the third main electrode wire or the fourth main electrode wire; and the multiple second branch electrode wires are arranged perpendicular to the first adjacent edge.

The spacing distance between any two adjacent second branch electrode wires is equal.

Alternatively, the first branch electrode wire and the second branch electrode wire are arranged at intervals.

The first branch electrode wire and the second branch electrode wire are connected to one main electrode wire; and the main electrode wire includes a first main electrode wire, a second main electrode wire, a third main electrode wire, and a fourth main electrode wire.

An actuator is provided, which employs the piezoelectric composite material.

A preparation method is provided. The preparation method is used to prepare the actuator, and includes the following steps:
pasting a rectangular piezoelectric ceramic sheet to be cut on a dicing tape;
setting a direction of the bottom edge of the rectangular piezoelectric ceramic sheet as a cutting step direction, setting a direction at a preset included angle with the cutting step direction as a cutting direction, cutting the rectangular piezoelectric ceramic sheet by using a cutting machine to obtain multiple piezoelectric ceramic blocks serving as a piezoelectric ceramic fiber array;
casting melted polymer colloid into gaps of the multiple piezoelectric ceramic blocks, performing curing and forming by using a hot press, and tearing off the dicing tape to obtain a piezoelectric fiber composite layer;
etching a positive electrode and a negative electrode on each of two parallelogram substrates by using a printed circuit technology, thus obtaining an upper interdigital electrode layer and a lower interdigital electrode layer;
bonding the upper interdigital electrode layer to the upper surface of the piezoelectric fiber composite layer by using the polymer colloid, bonding the lower interdigital electrode layer to the lower surface of the piezoelectric fiber composite layer by using the polymer colloid, and then performing curing treatment to obtain the piezoelectric composite material;
welding wires on the upper interdigital electrode layer and the lower interdigital electrode layer, respectively, and applying a direct-current voltage to the piezoelectric composite material through the wires for polarization treatment, thus obtaining an actuator.

Alternatively, the preset included angle ranges from 30 degrees to 60 degrees.

According to the specific embodiment provided by the invention, the invention discloses the following technical effects:

A piezoelectric composite material, an actuator and a preparation method of the actuator are provided by the present disclosure. The piezoelectric composite material includes an upper interdigital electrode layer, a piezoelectric fiber composite layer and a lower interdigital electrode layer which are arranged in sequence from top to bottom. The upper interdigital electrode layer, the piezoelectric fiber composite layer and the lower interdigital electrode layer each are of a parallelogram structure. A piezoelectric ceramic fiber array is embedded on the piezoelectric fiber composite layer; and the piezoelectric ceramic fiber array is of a parallelogram structure. By arranging the piezoelectric ceramic fiber array of the parallelogram structure, the effective area of an actuator can be increased, and then the actuation performance of the actuator can be improved.

### BRIEF DESCRIPTION OF THE DRAWINGS

To describe the technical solutions in the embodiments of the present disclosure or in the prior art more clearly, the following briefly introduces the accompanying drawings required for describing the embodiments. Apparently, the accompanying drawings in the following description show merely some embodiments of the present disclosure, and those of ordinary skill in the art may still derive other drawings from these accompanying drawings without creative efforts.

FIG. 1 is a structure schematic diagram of a piezoelectric composite material in accordance with an embodiment 1 of the present disclosure;

FIG. 2 is a structure schematic diagram of a lower interdigital electrode layer in accordance with an embodiment 1 of the present disclosure;

FIG. 3 is a flow chart of a preparation method in accordance with an embodiment 3 of the present disclosure.

In the drawings: 1—interdigital electrode layer; 2—polymer colloid layer; 3—piezoelectric fiber composite layer; 4—main electrode wire; 5—substrate; 6—rectangular piezoelectric ceramic sheet; 7—dicing tape; 8—piezoelectric ceramic fiber array; 9—polymer colloid in the gap of piezoelectric ceramic block.

### DETAILED DESCRIPTION OF THE EMBODIMENTS

The following clearly and completely describes the technical solutions in the embodiments of the present disclosure with reference to the accompanying drawings in the embodiments of the present disclosure. Apparently, the described embodiments are merely a part rather than all of the embodiments of the present disclosure. All other embodiments obtained by those of ordinary skill in the art based on the embodiments of the present disclosure without creative efforts shall fall within the protection scope of the present disclosure.

An objective of the present disclosure is to provide a piezoelectric composite material, an actuator, and a preparation method of the actuator. The piezoelectric composite material is applied to the actuator. By arranging the piezoelectric ceramic fiber array of the parallelogram structure, the effective area of the actuator can be increased, and then the actuation performance of the actuator can be improved.

To make the above objectives, features and advantages of the present disclosure more apparently and understandably, the present disclosure is further described in detail below with reference to the accompanying drawings and specific embodiments.

### Embodiment 1

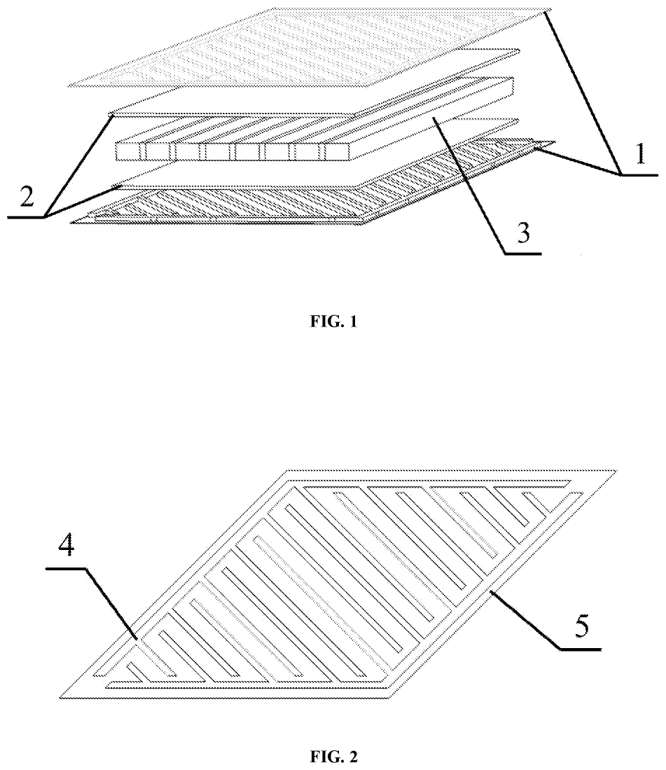

As shown in FIG. 1, the embodiment provides a piezoelectric composite material. The piezoelectric composite material includes interdigital electrode layers 1 (including an upper interdigital electrode layer and a lower interdigital electrode layer) and a piezoelectric fiber composite layer 3 which are arranged in sequence from top to bottom. The upper interdigital electrode layer, the piezoelectric fiber composite layer and the lower interdigital electrode layer each are of a parallelogram structure. A piezoelectric ceramic fiber array 8 is embedded on the piezoelectric fiber composite layer; and the piezoelectric ceramic fiber array is of a parallelogram structure. A first polymer colloid layer is provided between the upper interdigital electrode layer and the piezoelectric fiber composite layer, and a second polymer colloid layer is provided between the piezoelectric fiber composite layer and the lower interdigital electrode layer. The polymer colloid layer 2 includes a first polymer colloid layer and a second polymer colloid layer.

Specifically, the piezoelectric ceramic fiber array includes multiple piezoelectric ceramic blocks having the same shape and size. The multiple piezoelectric ceramic blocks each are of a parallelogram structure. The bottom edges of the multiple piezoelectric ceramic blocks are in the same direction; and the spacing distance between any two adjacent piezoelectric ceramic blocks is equal.

In addition, the upper interdigital electrode layer includes a substrate 5, a positive electrode, and a negative electrode. The positive electrode and the negative electrode are arranged on the same side surface of the substrate in an interdigital manner. The substrate is of a parallelogram structure. The upper interdigital electrode layer and the lower interdigital electrode layer have the same structure. As shown in FIG. 2, the structure of each of the lower interdigital electrode layer and the upper interdigital electrode layer also includes a substrate 5, a positive electrode, and a negative electrode. The positive electrode and the negative electrode are arranged on the same side surface of the substrate in an interdigital manner, and the substrate is of a parallelogram structure. The difference is that in the upper interdigital electrode layer, the positive electrode and the negative electrode are arranged on the lower surface of the substrate in an interdigital manner; and in the lower interdigital electrode layer, the positive electrode and the negative electrode are arranged on the upper surface of the substrate in an interdigital manner.

The negative electrode includes a first main electrode wire, a second main electrode wire and multiple first branch electrode wires. The first main electrode wire is arranged along the bottom edge of the substrate. The second main electrode wire is arranged along a first adjacent edge of the bottom edge of the substrate. The first adjacent edge is an adjacent edge with an obtuse angle with the bottom edge of the substrate. One end of the first main electrode wire intersects with one end of the second main electrode wire at an obtuse angle vertex on the bottom edge of the substrate. The length of the first main electrode wire is smaller than that of the bottom edge of the substrate, and the length of the second main electrode wire is smaller than that of the first adjacent edge. The multiple first branch electrode wires are arranged on the substrate in parallel. One end of each of the first branch electrode wires is connected to the first main electrode wire or the second main electrode wire. The multiple first branch electrode wires are arranged perpendicular to the first adjacent edge. The spacing distance between any two adjacent first branch electrode wires is equal.

The positive electrode includes a third main electrode wire, a fourth main electrode wire and multiple second branch electrode wires. The third main electrode wire is arranged along an opposite edge of the bottom edge of the substrate. The fourth main electrode wire is arranged along a second adjacent edge of the bottom edge of the substrate. The second adjacent edge is an adjacent edge with an acute angle with the bottom edge of the substrate. One end of the third main electrode wire intersects with one end of the fourth main electrode wire at an obtuse angle vertex on the second adjacent edge of the substrate. The length of the third main electrode wire is equal to that of the first main electrode wire. The length of the fourth main electrode wire is equal to that of the second main electrode wire. The multiple second branch electrode wires are arranged on the substrate in parallel. One end of each of the second branch electrode wires is connected to the third main electrode wire or the fourth main electrode wire. The multiple second branch electrode wires are arranged perpendicular to the first adjacent edge. The spacing distance between any two adjacent second branch electrode wires is equal.

The first branch electrode wire and the second branch electrode wire are arranged at intervals. The first branch electrode wire and the second branch electrode wire are connected to only one main electrode wire. The main electrode wire 4 includes a first main electrode wire, a second main electrode wire, a third main electrode wire, and a fourth main electrode wire.

### Embodiment 2

An actuator is provided in this embodiment, which employs the piezoelectric composite material of embodiment 1.

### Embodiment 3

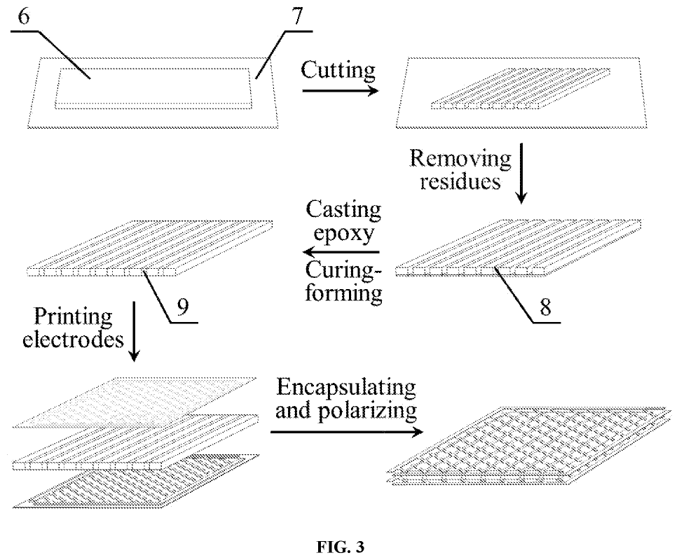

As shown in FIG. 3, a preparation method is provided in this embodiment. The preparation method is used to prepare the actuator of embodiment 2, and includes the following steps:

Step 1: A rectangular piezoelectric ceramic sheet 6 to be cut is pasted on a dicing tape 7; the rectangular piezoelectric ceramic sheet to be cut is wiped with absolute ethanol before pasting; the rectangular piezoelectric ceramic sheet is pasted on the center of the dicing tape, then the dicing tape is tightened and fixed to a cutting machine, and a long edge direction of the piezoelectric sheet is recorded as a first direction. The piezoelectric ceramic sheet is PZT, PMN-PT, KNN or BT series piezoelectric ceramics, the thickness of which is optional in the range of 0.1 mm to 0.5 mm. The dicing tape is a UV cutting protective film.

Step 2: A direction of the bottom edge of the rectangular piezoelectric ceramic sheet is a cutting step direction, a direction at a preset included angle with the cutting step direction is set as a cutting direction, and the rectangular piezoelectric ceramic sheet is cut by using a cutting machine, so as to obtain multiple piezoelectric ceramic blocks serving as a piezoelectric ceramic fiber array.

The preset included angle ranges from 30 degrees to 60 degrees. The piezoelectric ceramic sheet is mechanically cut in a cutting direction at a particular required included angle with the first direction, where the cutting direction is recorded as a second direction of the piezoelectric sheet, the first direction is used as a cutting step direction, and a cutting step spacing is fixed. After cutting, the residues of the ceramic sheet are taken out to obtain a parallelogram piezoelectric ceramic fiber array.

The width of the fiber (piezoelectric ceramic block) in the piezoelectric ceramic fiber array is continuously adjustable in the range from 0.5 mm to 2 mm by changing the cutting step spacing, and the fiber gap is continuously adjustable in the range from 0.1 mm to 0.25 mm by using cutting blades with different thicknesses.

Step 3: Melted polymer colloid is cast into gaps of the multiple piezoelectric ceramic blocks, and curing and forming are carried out by a hot press; and a piezoelectric fiber composite layer is obtained after tearing off the dicing tape. The polymer colloid in the gaps of the piezoelectric ceramic blocks is as shown in FIG. 3.

The prepared polymer colloid is used to pour the fiber gaps of the parallelogram piezoelectric array, then the parallelogram piezoelectric array after casting the polymer colloid is horizontally placed at the center of a worktable of the hot press, the pressure and temperature of the worktable are set, and a parallelogram piezoelectric fiber composite material is cured and formed after holding temperature and pressures for a period of time. After taking out the formed piezoelectric fiber composite material and tearing off the dicing tape on the lower surface, the upper and lower surfaces of the material are wiped with absolute ethanol for later use.

Here, thermosetting epoxy resin is used as the polymer colloid. For the piezoelectric composite material, the setting range of the curing pressure is from 0.1 MPa to 2 MPa, the setting range of the curing temperature is from 80° C. to 150° C., and the temperature/pressure holding time is from 120 min to 240 min.

Step 4: A positive electrode and a negative electrode are etched on each of two parallelogram substrates by using a printed circuit technology, so as to obtain an upper interdigital electrode layer and a lower interdigital electrode layer. By using the printed circuit technology and using polyimide as a substrate material, single-sided printed interdigital electrical patterns of the upper and lower surface electrodes are etched by using tinned copper: positive and negative electrode buses each are composed of two electrode wires parallel to the first and second directions, and the bus envelops an electrode coverage area of a parallelogram configuration. The positive and negative branch electrode wires extended from the positive and negative buses are perpendicular to the second direction. The size of the electrode effective region formed by the interdigital electrode wires is consistent with that of the parallelogram piezoelectric fiber composite material prepared above. The circuit patterns of the upper and lower surface electrodes are mirror-symmetrical. The width of the etched electrode wire is continuously adjustable in the range from 0.1 mm to 1.0 mm, and the spacing distance between the adjacent anisotropic electrode branches is continuously adjustable from 0.5 mm to 2.0 mm.

Step 5: The upper interdigital electrode layer is bonded to the upper surface of the piezoelectric fiber composite layer by using the polymer colloid, the lower interdigital electrode layer is bonded to the lower surface of the piezoelectric fiber composite layer by using the polymer colloid, and then the curing treatment is carried out to obtain the piezoelectric composite material of embodiment 1.

The surfaces of the prepared upper and lower interdigital electrode layers are wiped with absolute ethanol. The polymer colloid is uniformly coated on the upper and lower surfaces of the prepared parallelogram piezoelectric fiber composite material, and then the upper and lower interdigital electrodes are respectively pasted on the upper and lower surfaces of the material. The electrode layer and the piezoelectric composite layer are tightly bonded without bubbles, the effective region of the electrode layer coincides with the parallelogram piezoelectric composite layer, and isotropic electrode wires in the upper and lower interdigital electrode layers are strictly aligned. An obtained laminated structure consisting of the lower interdigital electrode layer, the piezoelectric fiber composite layer and the upper interdigital electrode layer is placed at the center of the worktable of the hot press, the pressure and temperature of the worktable are set, and the colloid between the electrode layer and the piezoelectric composite layer is completely cured after holding the temperature/pressure for a period of time; then the structure is taken out for trimming.

Thermosetting epoxy resin is used as the polymer colloid. For the polymer colloid, the setting range of the curing pressure is from 0.5 MPa to 5 MPa, the setting range of the curing temperature is from 80° C. to 150° C., and setting range of the temperature/pressure holding time is from 120 min to 240 min.

Step 6: Wires are welded on the upper interdigital electrode layer and the lower interdigital electrode layer, respectively, and a direct-current voltage is applied to the piezoelectric composite material through the wires for polarization treatment, thus obtaining the actuator of embodiment 2.

At a room temperature, the preparation of the device is completed by applying the direct-current voltage to the electrode for polarization treatment for a period of time. The direct current polarization voltage ranges from 1.5 kV to 6.0 kV and the polarization time ranges from 20 min to 60 min according to the spacing distance between adjacent anisotropic electrode branches.

The present disclosure is described in detail below by taking the parallelogram piezoelectric fiber composite material having an effective region length of 50 mm, a height of 30 mm, a thickness of 0.25 mm, and a vertex angle of 45 degrees, as well as the preparation of the actuator as the example.

Step 1: The unpolarized PZT-5H rectangular piezoelectric ceramic sheet having a length of 80 mm, a width of 30 mm and a thickness of 0.25 mm is wiped with absolute ethanol; the piezoelectric ceramic sheet is pasted on a dicing tape having a length of 200 mm, a width of 150 mm and a thickness of 0.1 mm. The rectangular piezoelectric sheet is pasted close to the center of the dicing tape as far as possible, and it is guaranteed that the piezoelectric sheet and the dicing tape are closely attached without bubbles.

Step 2: The dicing tape pasted with the piezoelectric sheet is tightened, and then is assembled on a cutting machine. A direction parallel to the long edge direction of the piezoelectric ceramic sheet is taken as the first direction, and a direction at an included angle of 45 degrees with the first direction is set as a second direction of the sheet. Cutting parameters are set, a cutting blade having a thickness of 0.1 mm is used, the first direction is used as a cutting step direction, the second direction is used as a cutting direction, a cutting step spacing is fixed to be 0.4 mm, the cutting thickness is 0.08 mm, and the total number of cutting times is 101. After cutting for 101 times, the residual parts on both sides of the piezoelectric ceramic sheet are removed to obtain a parallelogram piezoelectric array consisting of 100 piezoelectric ceramic fibers parallel to the second direction. The surface of the ceramic fiber array is wiped with absolute ethanol, and then ceramic fiber array is placed aside for later use.

Step 3: 50 g of E-44 epoxy resin, 10 g of low-molecular 650 polyamide resin curing agent and 10 g of dibutyl ester toughening agent are respectively weighed with a balance, are stirred and mixed fully with a glass rod, and then are subjected to bubble evacuation to complete the preparation of polymer matrix. The gaps of the parallelogram piezoelectric ceramic fiber array are filled with the cast polymer matrix, and then the parallelogram piezoelectric ceramic fiber array is placed at the center of the worktable of the hot press. The pressure and temperature of the worktable are set as 0.5 MPa and 100° C., respectively, and the polymer matrix is completely cured after holding temperature/pressure for 180 min. The formed piezoelectric fiber composite material is taken out for tearing off the dicing tape on the lower surface, then the upper and lower surfaces of the piezoelectric composite layer are wiped with absolute ethanol, and the piezoelectric fiber composite material is placed aside for later user.

Step 4: By using a printed circuit technology, the upper surface parallelogram flexible interdigital electrode is prepared by etching electrode wires on the surface of a polyimide insulating layer with tinned copper, where the electrode pattern is shown in FIG. 2. The width of the etched electrode wire is 0.2 mm, the spacing distance between adjacent anisotropic electrode branches is 0.5 mm, and both positive and negative branch electrodes are perpendicular to the second direction of the piezoelectric sheet, that is, perpendicular to the piezoelectric fiber in the piezoelectric composite layer. The lower surface interdigital electrode pattern is kept mirror symmetric with the upper surface interdigital electrode pattern, and the shape and size of the electrode effective region are consistent with those of the piezoelectric fiber composites prepared above. The prepared parallelogram upper and lower interdigital electrode layers are wiped with absolute ethanol, then are placed aside for later use.

Step 5: 10 g of E-44 epoxy resin, 2 g of low-molecular 650 polyamide resin curing agent and 2 g of dibutyl ester toughening agent are respectively weighed with a balance, are stirred and mixed fully with a glass rod, and then are subjected to bubble evacuation to complete the preparation of polymer matrix. The colloid is uniformly coated on the upper and lower surfaces of the parallelogram piezoelectric fiber composite material prepared above. The prepared upper and lower interdigital electrode layers are respectively pasted on the upper and lower surfaces of the prepared parallelogram piezoelectric fiber composite material, it is guaranteed in the pasting operation process that the electrode layer and the piezoelectric composite layer are closely attached without bubbles; the effective region of the electrode layer coincides with the parallelogram piezoelectric composite layer; and the isotropic electrode wires in the upper and lower interdigital electrode layers are strictly aligned.

Step 6: A laminated structure consisting of the lower interdigital electrode layer, the piezoelectric fiber composite layer and the upper interdigital electrode layer obtained step 5 is placed at the center of the worktable of the hot press, the pressure and temperature of the worktable are set to be 2.5 MPa and 100° C., respectively, and the colloid between the electrode layer and the piezoelectric composite layer is completely cured after holding the temperature/pressure for 180 min. The formed parallelogram piezoelectric fiber composite actuator is taken out and trimmed.

Step 7: Positive and negative electrode wires are welded to the formed actuator in step 6, 1.5 kV of direct-current polarization voltage is applied at a room temperature, after polarizing for 30 min, the preparation of the piezoelectric fiber composite material actuator of parallelogram configuration is completed.

The piezoelectric composite material, the actuator and the preparation method of the actuator provided by the present disclosure have low requirements on the equipment and are easy to achieve. The obtained piezoelectric actuator device has a novel configuration, which overcomes the problem of limited effective area when the traditional piezoelectric fiber composite material actuator of rectangular configuration actuates the torsional deformation of the structure, and can effectively satisfy the torsional deformation requirements of the actual structure. Moreover, the size of the actuator is accurate and controllable, and the cutting direction for cutting the piezoelectric ceramic sheet by the cutting machine can be adjusted according to the practical requirements, so that the piezoelectric fiber array arranged in a specific direction can be obtained, and the piezoelectric composite layer of the special parallelogram configuration can be obtained by casting polymer matrix. Meanwhile, the piezoelectric phase volume fraction and the effective region area in the parallelogram piezoelectric composite layer can be effectively controlled by adjusting the cutting step and the size of the piezoelectric fiber array, so as to meet different requirements in practical application.

In addition, in order to achieve the effective polarization and actuation of piezoelectric fibers, a suitable parallelogram interdigital electrode layer is designed for the piezoelectric fiber composite material of parallelogram configuration. The positive and negative branch electrode wires in the upper and lower electrode layers are perpendicular to the direction of piezoelectric fibers in the piezoelectric composite layer, the effectiveness of the electric field in the piezoelectric phase during the polarization and actuation is ensured, the adverse effects of non-ideal polarization and actuation electric fields on the performance of the device are avoided, and the systematic preparation of the structure and performance of the piezoelectric fiber composite material of parallelogram configuration can be easily achieved.

Embodiments in this specification are described in a progressive manner, each embodiment focuses on differences from other embodiments, and the same and similar parts between the embodiments can be referred to each other. Since the system disclosed in the embodiments correspond to the method disclosed by the embodiments, the description thereof is relatively simple, and for relevant matters references may be made to the description of the method.

Several examples are used for illustration of the principles and implementation methods of the present disclosure. The description of the embodiments is merely used to help illustrate the method and its core principles of the present disclosure. In addition, those of ordinary skill in the art can make various modifications in terms of specific embodiments and scope of application in accordance with the teachings of the present disclosure. In conclusion, the content of this specification shall not be construed as a limitation to the present disclosure.

What is claimed is:

1. A piezoelectric composite material, comprising: an upper interdigital electrode layer, a piezoelectric fiber composite layer and a lower interdigital electrode layer which are arranged in sequence from top to bottom;
the upper interdigital electrode layer, the piezoelectric fiber composite layer and the lower interdigital electrode layer each are of a parallelogram structure;
a piezoelectric ceramic fiber array is embedded on the piezoelectric fiber composite layer; and the piezoelectric ceramic fiber array is of a parallelogram structure.

2. The piezoelectric composite material according to claim 1, wherein a first polymer colloidal layer is provided between the upper interdigital electrode layer and the piezoelectric fiber composite layer; and
a second polymer colloid layer is provided between the piezoelectric fiber composite layer and the lower interdigital electrode layer.

3. The piezoelectric composite material according to claim 1, wherein the piezoelectric ceramic fiber array comprises a plurality of piezoelectric ceramic blocks;
the plurality of piezoelectric blocks have the same shape and size, and the plurality of piezoelectric ceramic blocks each are of a parallelogram structure;
the bottom edges of the plurality of piezoelectric ceramic blocks are in the same direction; and the spacing distance between any two adjacent piezoelectric ceramic blocks is equal.

4. The piezoelectric composite material according to claim 1, wherein the upper interdigital electrode layer comprises a substrate, a positive electrode, and a negative electrode;
the positive electrode and the negative electrode are arranged on the same side surface of the substrate in an interdigital manner; and
the substrate is of a parallelogram structure.

5. The piezoelectric composite material according to claim 4, wherein the positive electrode comprises a first main electrode wire, a second main electrode wire, and a plurality of first branch electrode wires;
the first main electrode wire is arranged along the bottom edge of the substrate;
the second main electrode wire is arranged along a first adjacent edge of the bottom edge of the substrate; the first adjacent edge is an adjacent edge with an obtuse angle with the bottom edge of the substrate;
one end of the first main electrode wire intersects with one end of the second main electrode wire at an obtuse angle vertex on the bottom edge of the substrate;
the length of the first main electrode wire is smaller than that of the bottom edge of the substrate;
the length of the second main electrode wire is smaller than that of the first adjacent edge;
the plurality of first branch electrode wires are arranged on the substrate in parallel;
one end of each of the first branch electrode wires is connected to the first main electrode wire or the second main electrode wire; and the plurality of first branch electrode wires are arranged perpendicular to the first adjacent edge; and
the spacing distance between any two adjacent first branch electrode wires is equal.

6. The piezoelectric composite material according to claim 5, wherein the negative electrode comprises a third main electrode wire, a fourth main electrode wire, and a plurality of second branch electrode wires;
the third main electrode wire is arranged along an opposite edge of the bottom edge of the substrate;
the fourth main electrode wire is arranged along a second adjacent edge of the bottom edge of the substrate; the second adjacent edge is an adjacent edge with an acute angle with the bottom edge of the substrate;
one end of the third main electrode wire intersects with one end of the fourth main electrode wire at an obtuse angle vertex on the bottom edge of the substrate;
the length of the third main electrode wire is equal to that of the first main electrode wire;
the length of the fourth main electrode wire is equal to that of the second main electrode wire;
the plurality of second branch electrode wires are arranged on the substrate in parallel;
one end of each of the second branch electrode wires is connected to the third main electrode wire or the fourth main electrode wire; and the plurality of second branch electrode wires are arranged perpendicular to the first adjacent edge;
the spacing distance between any two adjacent second branch electrode wires is equal.

7. The piezoelectric composite material according to claim 6, wherein the first branch electrode wires and the second branch electrode wires are arranged at intervals;
the first branch electrode wires and the second branch electrode wires are connected to one main electrode wire; and the main electrode wire comprises a first main electrode wire, a second main electrode wire, a third main electrode wire, and a fourth main electrode wire.

8. An actuator, wherein the actuator employs the piezoelectric composite material according to claim 1.

9. The actuator according to claim 8, wherein a first polymer colloidal layer is provided between the upper interdigital electrode layer and the piezoelectric fiber composite layer; and
a second polymer colloid layer is provided between the piezoelectric fiber composite layer and the lower interdigital electrode layer.

10. The actuator according to claim 8, wherein the piezoelectric ceramic fiber array comprises a plurality of piezoelectric ceramic blocks;
the plurality of piezoelectric blocks have the same shape and size, and the plurality of piezoelectric ceramic blocks each are of a parallelogram structure;
the bottom edges of the plurality of piezoelectric ceramic blocks are in the same direction; and the spacing distance between any two adjacent piezoelectric ceramic blocks is equal.

11. The actuator according to claim 8, wherein the upper interdigital electrode layer comprises a substrate, a positive electrode, and a negative electrode;
the positive electrode and the negative electrode are arranged on the same side surface of the substrate in an interdigital manner; and
the substrate is of a parallelogram structure.

12. The actuator according to claim 11, wherein the positive electrode comprises a first main electrode wire, a second main electrode wire, and a plurality of first branch electrode wires;
the first main electrode wire is arranged along the bottom edge of the substrate;
the second main electrode wire is arranged along a first adjacent edge of the bottom edge of the substrate; the first adjacent edge is an adjacent edge with an obtuse angle with the bottom edge of the substrate;
one end of the first main electrode wire intersects with one end of the second main electrode wire at an obtuse angle vertex on the bottom edge of the substrate;
the length of the first main electrode wire is smaller than that of the bottom edge of the substrate;
the length of the second main electrode wire is smaller than that of the first adjacent edge;
the plurality of first branch electrode wires are arranged on the substrate in parallel;
one end of each of the first branch electrode wires is connected to the first main electrode wire or the second main electrode wire; and the plurality of first branch electrode wires are arranged perpendicular to the first adjacent edge; and
the spacing distance between any two adjacent first branch electrode wires is equal.

13. The actuator according to claim 12, wherein the negative electrode comprises a third main electrode wire, a fourth main electrode wire, and a plurality of second branch electrode wires;
the third main electrode wire is arranged along an opposite edge of the bottom edge of the substrate;
the fourth main electrode wire is arranged along a second adjacent edge of the bottom edge of the substrate; the second adjacent edge is an adjacent edge with an acute angle with the bottom edge of the substrate;
one end of the third main electrode wire intersects with one end of the fourth main electrode wire at an obtuse angle vertex on the bottom edge of the substrate;
the length of the third main electrode wire is equal to that of the first main electrode wire;
the length of the fourth main electrode wire is equal to that of the second main electrode wire;
the plurality of second branch electrode wires are arranged on the substrate in parallel;
one end of each of the second branch electrode wires is connected to the third main electrode wire or the fourth main electrode wire; and the plurality of second branch electrode wires are arranged perpendicular to the first adjacent edge;
the spacing distance between any two adjacent second branch electrode wires is equal.

14. The actuator according to claim 13, wherein the first branch electrode wires and the second branch electrode wires are arranged at intervals;
the first branch electrode wires and the second branch electrode wires are connected to one main electrode wire; and the main electrode wire comprises a first main electrode wire, a second main electrode wire, a third main electrode wire, and a fourth main electrode wire.

15. A preparation method, wherein the preparation method is used to prepare the actuator according to claim 8, and the method comprises:
pasting a rectangular piezoelectric ceramic sheet to be cut on a dicing tape;
setting a direction of the bottom edge of the rectangular piezoelectric ceramic sheet as a cutting step direction, setting a direction at a preset included angle with the cutting step direction as a cutting direction, cutting the rectangular piezoelectric ceramic sheet by using a cutting machine to obtain a plurality of piezoelectric ceramic blocks serving as a piezoelectric ceramic fiber array;
casting melted polymer colloid into gaps of the plurality of piezoelectric ceramic blocks, performing curing and forming by using a hot press, and tearing off the dicing tape to obtain a piezoelectric fiber composite layer;
etching a positive electrode and a negative electrode on each of two parallelogram substrates by using a printed circuit technology, thus obtaining an upper interdigital electrode layer and a lower interdigital electrode layer;
bonding the upper interdigital electrode layer to the upper surface of the piezoelectric fiber composite layer by using the polymer colloid, bonding the lower interdigital electrode layer to the lower surface of the piezoelectric fiber composite layer by using the polymer colloid, and then performing curing treatment to obtain the piezoelectric composite material;
welding wires on the upper interdigital electrode layer and the lower interdigital electrode layer, respectively, and applying a direct-current voltage to the piezoelectric composite material through the wires for polarization treatment, thus obtaining an actuator.

16. The preparation method according to claim 15, wherein the preset included angle ranges from 30 degrees to 60 degrees.
